(19) United States
(12) Patent Application Publication
(10) Pub. No.: US 2011/0108966 A1
(43) Pub. Date: May 12, 2011

(54) INTEGRATED CIRCUIT PACKAGING SYSTEM WITH CONCAVE TRENCHES AND METHOD OF MANUFACTURE THEREOF

(76) Inventors: Henry Descalzo Bathan, Singapore (SG); Zigmund Ramirez Camacho, Singapore (SG); Emmanuel Espiritu, Singapore (SG)

(21) Appl. No.: 12/729,631

(22) Filed: Mar. 23, 2010

Related U.S. Application Data
(60) Provisional application No. 61/260,021, filed on Nov. 11, 2009.

(51) Int. Cl. H01L 23/495; H01L 21/50

(52) U.S. Cl. 257/676; 438/123; 438/118; 257/E23.052; 257/E21.499

(57) ABSTRACT

A method of manufacture of an integrated circuit packaging system includes: providing a conductive layer having a first surface and a second surface; forming first concave trenches in the first surface of the conductive layer and the first concave trenches are connected by a first flat region of the first surface; connecting an integrated circuit to the first flat region with a conductive interconnect; encapsulating the integrated circuit with an encapsulation that fills the first concave trenches; and forming second concave trenches having a similar size in the second surface of the conductive layer with the second concave trenches connected by a second flat region that is larger than the first flat region, and the second concave trenches are formed through the conductive layer to expose the encapsulation.

### CROSS-REFERENCE TO RELATED APPLICATION(S)

This application claims the benefit of U.S. Provisional Patent Application Ser. No. 61/260,021 filed Nov. 11, 2009, and the subject matter thereof is incorporated herein by reference thereto.

### TECHNICAL FIELD

The present invention relates generally to an integrated circuit packaging system and more particularly to a system for an integrated circuit packaging system with quad flat no-lead package.

### BACKGROUND

The rapidly growing market for portable electronics devices, e.g. cellular phones, laptop computers, and PDAs, is an integral facet of modern life. The multitude of portable devices represents one of the largest potential market opportunities for next generation packaging. These devices have unique attributes that have significant impacts on manufacturing integration, in that they must be generally small, lightweight, and rich in functionality and they must be produced in high volumes at relatively low cost.

As an extension of the semiconductor industry, the electronics packaging industry has witnessed ever-increasing commercial competitive pressures, along with growing consumer expectations and the diminishing opportunities for meaningful product differentiation in the marketplace.

Packaging, materials engineering, and development are at the very core of these next generation electronics insertion strategies outlined in road maps for development of next generation products. Future electronic systems may be more intelligent, have higher density, use less power, operate at higher speed, and may include mixed technology devices and assembly structures at lower cost than today.

Current packaging suppliers are struggling to accommodate the high-speed computer devices that are projected to exceed one TeraHertz (THz) in the near future. The current technologies, materials, equipment, and structures offer challenges to the basic assembly of these new devices while still not adequately addressing cooling and reliability concerns.

The envelope of technical capability of next level interconnect assemblies are not yet known, and no clear cost effective technology has yet been identified. Beyond the performance requirements of next generation devices, the industry now demands that cost be a primary product differentiator in an attempt to meet profit goals.

As a result, the road maps are driving electronics packaging to precision, ultra miniature form factors, which require automation in order to achieve acceptable yield. These challenges demand not only automation of manufacturing, but also the automation of data flow and information to the production manager and customer.

There have been many approaches to addressing the advanced packaging requirements of microprocessors and portable electronics with successive generations of semiconductors. Many industry road maps have identified significant gaps between the current semiconductor capability and the available supporting electronic packaging technologies. The limitations and issues with current technologies include increasing clock rates, EMI radiation, thermal loads, second level assembly reliability stresses and cost.

As these package systems evolve to incorporate more components with varied environmental needs, the pressure to push the technological envelope becomes increasingly challenging. More significantly, with the ever-increasing complexity, the potential risk of error increases greatly during manufacture.

In view of the ever-increasing commercial competitive pressures, along with growing consumer expectations and the diminishing opportunities for meaningful product differentiation in the marketplace, it is critical that answers be found for these problems. Additionally, the need to reduce costs, reduce production time, improve efficiencies and performance, and meet competitive pressures, adds an even greater urgency to the critical necessity for finding answers to these problems.

Thus, a need remains for smaller footprints and more robust packages and methods for manufacture. Solutions to these problems have been long sought but prior developments have not taught or suggested any solutions and, thus, solutions to these problems have long eluded those skilled in the art.

### DISCLOSURE OF THE INVENTION

The present invention provides a method of manufacture of an integrated circuit packaging system including: providing a conductive layer having a first surface and a second surface; forming first concave trenches in the first surface of the conductive layer and the first concave trenches are connected by a first flat region of the first surface; connecting an integrated circuit to the first flat region with a conductive interconnect; encapsulating the integrated circuit with an encapsulation that fills the first concave trenches; and forming second concave trenches having a similar size in the second surface of the conductive layer with the second concave trenches connected by a second flat region that is larger than the first flat region, and the second concave trenches are formed through the conductive layer to expose the encapsulation.

The present invention provides an integrated circuit packaging system, including: a conductive layer having a first surface with first concave surfaces that are connected by a first flat region of the first surface, and the conductive layer has a second surface with second concave surfaces having a similar size that are connected by a second flat region that is larger than the first flat region; an integrated circuit connected to the first flat region with a conductive interconnect; and an encapsulation that encapsulates the integrated circuit and that encapsulates the first concave surfaces, and the encapsulation is exposed by the second concave surfaces.

Certain embodiments of the invention have other steps or elements in addition to or in place of those mentioned above. The steps or element will become apparent to those skilled in the art from a reading of the following detailed description when taken with reference to the accompanying drawings.

### BRIEF DESCRIPTION OF THE DRAWINGS

FIG. 1 is a cross-sectional view of an integrated circuit packaging system along a section line 1-1 of FIG. 2 in a first embodiment of the present invention.

FIG. 2 is a bottom view of the integrated circuit packaging system.

FIG. 3 is a cross-sectional view of a portion of the integrated circuit packaging system along the section line 1-1 of FIG. 2 in preparatory phase of manufacture.

FIG. 4 is a cross-sectional view of the integrated circuit packaging system of FIG. 3 after an exposure phase.

FIG. 5 is a cross-sectional view of the integrated circuit packaging system of FIG. 4 after a development phase.

FIG. 6 is a cross-sectional view of the integrated circuit packaging system of FIG. 5 after a first etching phase.

FIG. 7 is a cross-sectional view of the integrated circuit packaging system of FIG. 6 after a die attach phase.

FIG. 8 is a cross-sectional view of the integrated circuit packaging system of FIG. 7 after an encapsulation phase.

FIG. 9 is a cross-sectional view of the integrated circuit packaging system of FIG. 8 after a second etching phase.

FIG. 10 is a flow chart of a method of manufacture of an integrated circuit packaging system of FIG. 1 in a further embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known circuits, system configurations, and process steps are not disclosed in detail.

The drawings showing embodiments of the system are semi-diagrammatic and not to scale and, particularly, some of the dimensions are for the clarity of presentation and are shown exaggerated in the drawing FIGs. Similarly, although the views in the drawings for ease of description generally show similar orientations, this depiction in the FIGs. is arbitrary for the most part. Generally, the invention can be operated in any orientation.

In addition, where multiple embodiments are disclosed and described having some features in common, for clarity and ease of illustration, description, and comprehension thereof, similar and like features from one to another will ordinarily be described with like reference numerals. The embodiments have been numbered first embodiment, second embodiment, etc. as a matter of descriptive convenience and are not intended to have any other significance or provide limitations for the present invention.

For expository purposes, the term “horizontal” as used herein is defined as a plane parallel to the plane or surface of the substrate, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane, as shown in the figures. The term “on” means that there is direct contact between elements or components with no intervening material.

The term “processing” as used herein includes deposition of material or photoresist, patterning, exposure, development, etching, cleaning, and/or removal of the material or photoresist as required in forming a described structure.

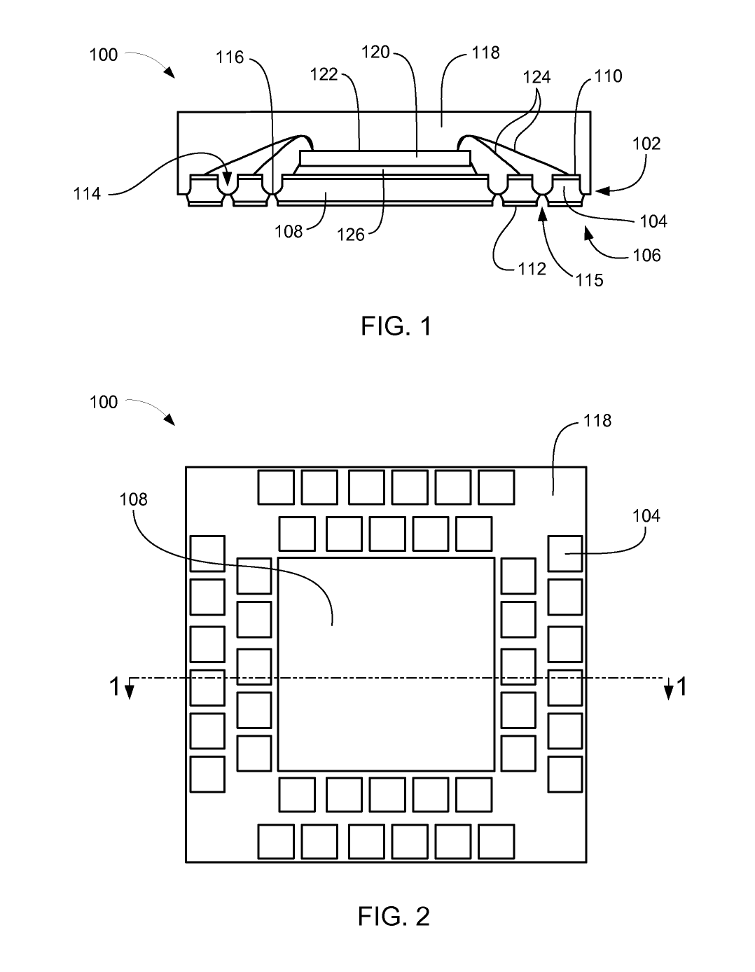

Referring now to FIG. 1, therein is shown a cross-sectional view of an integrated circuit packaging system 100 along a section line 1-1 of FIG. 2 in a first embodiment of the present invention. The integrated circuit packaging system 100 is shown having a conductive layer 102 such as a copper or a laminated conductive substrate. The conductive layer 102 is shown having terminal portions 104 along outer edges 106 of the conductive layer 102. The conductive layer 102 is also shown having a paddle 108 near the center of the conductive layer 102.

The terminals 104 have a flat upper surface 110 and a flat bottom surface 112, which are substantially flat. The flat upper surface 110 and the flat bottom surface 112 of the terminals 104 are separated by concave trenches 114. The concave trenches 114 separating the upper surfaces 110 of the terminals 104 are larger than the concave trenches 114 separating the bottom surfaces 112 of the terminals 104. This difference in relative size of the concave trenches 114 has the effect of forming the flat upper surface 110 of the terminal 104 having a smaller surface area than the bottom surface 112.

The concave trenches 114 separating the flat upper surface 110 create a larger surface area and a larger distance from a bottom region 116 of the concave trench 114 to the flat upper surface 110 of the terminal 104. The concave trenches 114 separating the bottom surfaces 112 of the terminals 104 are of substantially similar size.

It has been discovered that the larger surface area from the bottom region 116 of the concave trench 114 extending to the flat upper surface 110 greatly increases adhesion to an encapsulation 118 providing greater protection and defenses from environmental and mechanical stresses.

Mounted above the paddle 108 is an integrated circuit 120 such as a wire-bonded die with an active side 122. The active side 122 of the integrated circuit 120 is connected to the upper surfaces 110 of the terminals 104 with conductive interconnects such as bond wires 124. The integrated circuit 120 is attached to the paddle 108 with a die attach adhesive 126.

It has been discovered that the flat upper surface 110 of the terminal can be relatively small in comparison to the flat bottom surface 112 because only a small stitch bond from the integrated circuit 120 needs to be made to the top of the terminal 104 while the flat bottom surface 112 of the terminal 104 should be larger than the flat upper surface 110 so a large solder ball (not shown) can be attached to provide electrical and mechanical connection to a printed circuit board (not shown).

The encapsulation 118 encapsulates the integrated circuit 120 and the bond wires 124. The encapsulation 118 also encapsulates the terminals 104 from the upper surfaces 110 to the bottom region 116 of the concave trenches 114. The bottom surfaces 112 and the concave trenches 114 separating the bottom surfaces 112 of the terminals 104 are not encapsulated by the encapsulation 118.

Referring now to FIG. 2, therein is shown a bottom view of the integrated circuit packaging system 100. The terminals 104 are shown substantially square but they may be of any configuration which aids in integrating the integrated circuit packaging system 100 into an external system (not shown).

The encapsulation 118 is shown surrounding the terminals 104 and the paddle 108 while leaving the paddle 108 and the terminals 104 exposed.

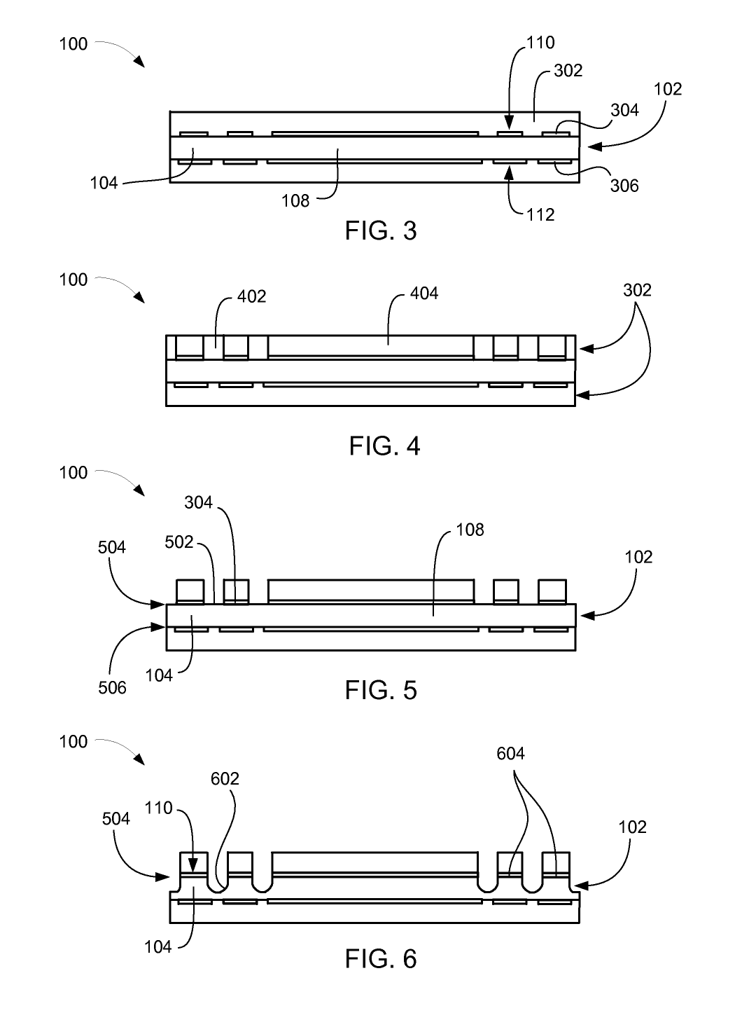

Referring now to FIG. 3, therein is shown a cross-sectional view of a portion of the integrated circuit packaging system 100 along the section line 1-1 of FIG. 2 in preparatory phase of manufacture. The integrated circuit packaging system 100 is shown having resist 302 deposited above and below the conductive layer 102. The conductive layer 102 is further shown having portions of the paddle 108 and portions of the terminals 104 etched into the conductive layer 102.

The portions of the terminals 104 that are etched into the conductive layer 102 are wire bonding sections 304 on the flat upper surface 110 of the terminals 104 and external connections 306 on the flat bottom surface 112 of the terminals 104.

Referring now to FIG. 4, therein is shown a cross-sectional view of the integrated circuit packaging system 100 of FIG. 3 after an exposure phase. The integrated circuit packaging system 100 is shown having the resist 302 such as dry film resist with exposed portions 402 that have been exposed to certain light source (e.g. UV light (not shown)), as a result, the dissolvability of the resist 302 to developer solution (not shown) is changed. The exposed portions 402 of the resist 302 is dissolvable with the developer solution, while an unexposed portion 404 remains undissolvable.

Referring now to FIG. 5, therein is shown a cross-sectional view of the integrated circuit packaging system 100 of FIG. 4 after a development phase. The integrated circuit packaging system 100 is shown having portions 502 of the conductive layer 102 exposed between the wire bonding sections 304 of the terminals 104.

The exposed portions 402 of FIG. 4 have been removed by developer solution (not shown). The conductive layer 102 is shown having a first surface 504 and a second surface 506.

Referring now to FIG. 6, therein is shown a cross-sectional view of the integrated circuit packaging system 100 of FIG. 5 after a first etching phase. The integrated circuit packaging system 100 is shown having first concave surfaces such as first concave trenches 602 etched into the first surface 504 of the conductive layer 102.

The first concave trenches 602 etched in the first surface 504 are connected by first flat regions 604. The first concave trenches 602 are shown as being etched more than half way through the conductive layer 102.

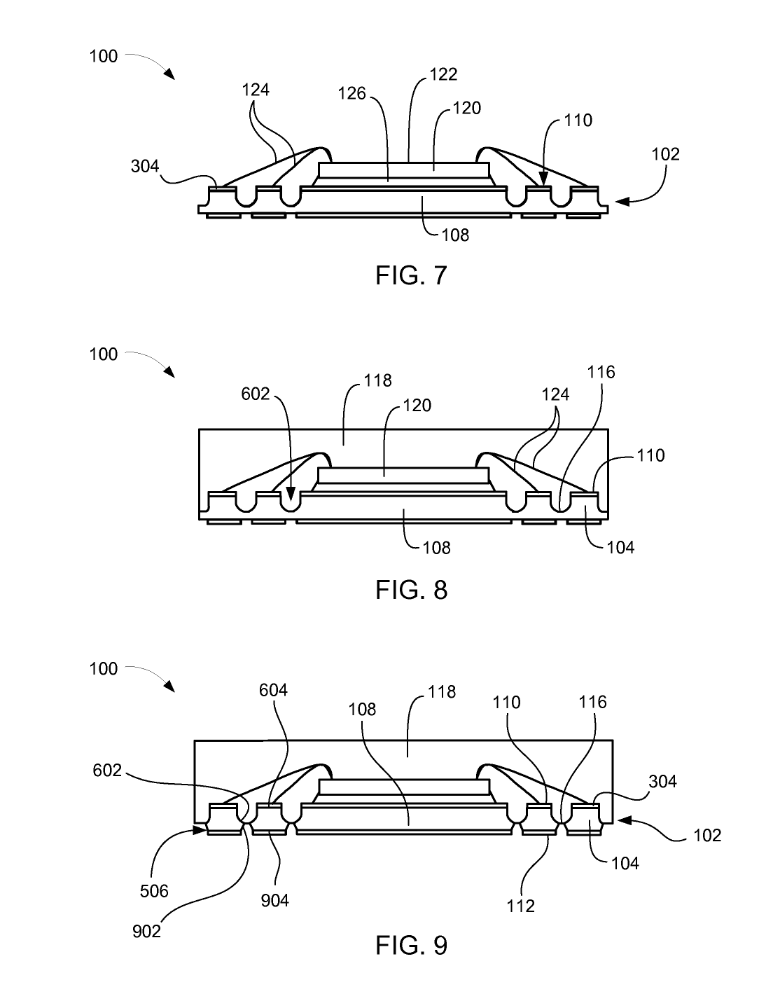

Referring now to FIG. 7, therein is shown a cross-sectional view of the integrated circuit packaging system 100 of FIG. 6 after a die attach phase. The integrated circuit packaging system 100 is shown having the integrated circuit 120 attached to the paddle 108 with the die attach adhesive 126.

The integrated circuit 120 is also shown having the active side 122 connected to the wire bonding sections 304 with the bond wires 124. Further, the resist 302 of FIG. 3 is shown completely removed from the conductive layer 102. The wire bonding sections 304 of the flat upper surface 110 may be plated with nickel, palladium, and gold.

Referring now to FIG. 8, therein is shown a cross-sectional view of the integrated circuit packaging system 100 of FIG. 7 in an encapsulation phase. The integrated circuit packaging system 100 is shown having the encapsulation 118 encapsulating the integrated circuit 120 and the bond wires 124. The encapsulation 118 also encapsulates the terminals 104 from the upper surfaces 110 to the bottom regions 116 of the first concave trenches 602 separating the upper surfaces 110 of the terminals 104.

Referring now to FIG. 9, therein is shown a cross-sectional view of the integrated circuit packaging system 100 of FIG. 8 after a second etching phase. The integrated circuit packaging system 100 is shown having second concave surfaces such as second concave trenches 902 etched into the second surface 506.

The second concave trenches 902 etched in the second surface 506 are connected by second flat regions 904. The second concave trenches 902 are shown as being smaller than the first concave trenches 602. Further the second flat regions 904 connecting the second concave trenches 602 are substantially smaller than the first flat regions 604 connecting the first concave trenches 602.

The second concave trenches 902 etches entirely through the conductive layer 102 to expose the encapsulation 118 near the bottom region 116 of the first concave trenches 602.

It has been discovered that the first concave trenches 602 should be larger than the second concave trenches 902. This difference creates a larger length that has been discovered to protect the flat upper surface 110 from the etching solution used on the flat bottom surface 112 thus insulating the wire bonding sections 304 from erosion during the second etching phase of manufacture.

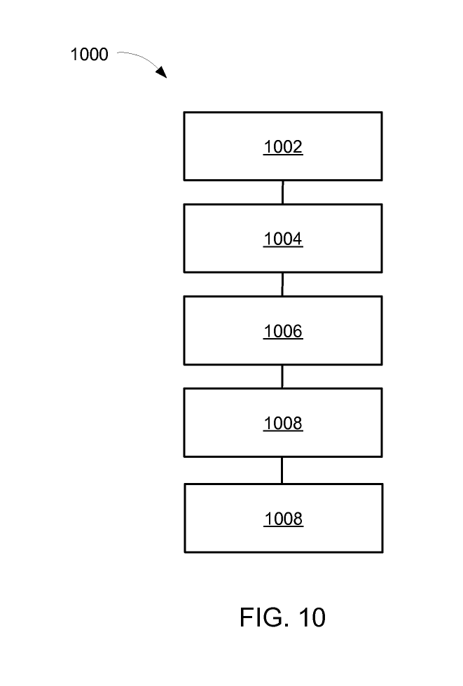

Referring now to FIG. 10, therein is shown a flow chart of a method 1000 of manufacture of the integrated circuit packaging system 100 of FIG. 1 in a further embodiment of the present invention. The method 1000 includes providing a conductive layer having a first surface and a second surface in a block 1002; forming first concave trenches in the first surface of the conductive layer and the first concave trenches are connected by a first flat region of the first surface in a block 1004; connecting an integrated circuit to the first flat region with a conductive interconnect in a block 1006; encapsulating the integrated circuit with an encapsulation that fills the first concave trenches in a block 1008; and forming second concave trenches in the second surface of the conductive layer with the second concave trenches connected by a second flat region that is larger than the first flat region, and the second concave trenches are formed through the conductive layer to expose the encapsulation in a block 1010.

Thus, it has been discovered that the concave trench system of the present invention furnishes important and heretofore unknown and unavailable solutions, capabilities, and functional aspects for integrated circuit packaging system configurations. The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A method of manufacturing an integrated circuit packaging system comprising:
providing a conductive layer having a first surface and a second surface;
forming first concave trenches in the first surface of the conductive layer and the first concave trenches are connected by a first flat region of the first surface;
connecting an integrated circuit to the first flat region with a conductive interconnect;
encapsulating the integrated circuit with an encapsulation that fills the first concave trenches; and
forming second concave trenches having a similar size in the second surface of the conductive layer with the second concave trenches connected by a second flat region that is larger than the first flat region, and the second concave trenches are formed through the conductive layer to expose the encapsulation.

2. The method as claimed in claim 1 wherein:
forming the first concave trenches includes forming a terminal along an outer edge and a paddle near the center of the conductive layer; and
further comprising:
attaching the integrated circuit to the paddle.

3. The method as claimed in claim 1 wherein:
forming the second concave trenches includes forming a terminal having a bottom surface that is substantially square.

4. The method as claimed in claim 1 wherein:
connecting the integrated circuit to the first flat region with the conductive interconnects includes connecting the integrated circuit to the first flat region with bond wires.

5. The method as claimed in claim 1 wherein:
forming the first concave trenches includes forming a terminal along an outer edge and a paddle near the center of the conductive layer.

6. A method of manufacture of an integrated circuit packaging system comprising:
providing a conductive layer having a first surface and a second surface;
forming first concave trenches in the first surface of the conductive layer with the first concave trenches connected by a first flat region of the first surface, and the first concave trenches form a paddle;
attaching an integrated circuit to the paddle with a die attach adhesive;
connecting the integrated circuit to the first flat region with a conductive interconnect;
encapsulating the integrated circuit and the conductive interconnects with an encapsulation that fills the first concave trenches; and
forming second concave trenches having a similar size in the second surface of the conductive layer with the second concave trenches connected by a second flat region that is larger than the first flat region, and the second concave trenches are formed through the conductive layer to expose the encapsulation and the second concave trenches are smaller than the first concave trenches.

7. The method as claimed in claim 6 wherein:
forming the second concave trenches includes forming the second concave trenches to intersect the bottom region of the first concave trenches.

8. The method as claimed in claim 6 wherein:
providing a conductive layer includes forming the conductive layer with nickel, gold, palladium, copper, or a combination thereof.

9. The method as claimed in claim 6 further comprising:
forming wire bonding sections on the first flat region; and
wherein:
connecting the integrated circuit includes connecting integrated circuit to the wire bonding sections with bond wires.

10. The method as claimed in claim 6 wherein:
forming the first concave trenches creates a substantially larger area for bonding to the encapsulation than the second concave trenches.

11. An integrated circuit packaging system comprising:
a conductive layer having a first surface with first concave surfaces that are connected by a first flat region of the first surface, and the conductive layer has a second surface with second concave surfaces having a similar size that are connected by a second flat region that is larger than the first flat region;
an integrated circuit connected to the first flat region with a conductive interconnect; and
an encapsulation that encapsulates the integrated circuit and that encapsulates the first concave surfaces, and the encapsulation is exposed by the second concave surfaces.

12. The system as claimed in claim 11 wherein:
the first concave surfaces form a terminal along an outer edge and a paddle near the center of the conductive layer.

13. The system as claimed in claim 11 wherein:
the second concave surfaces form a terminal having a bottom surface that is substantially square.

14. The system as claimed in claim 11 wherein:
the first concave surfaces form a terminal along an outer edge and a paddle near the center of the conductive layer; and
the integrated circuit is attached to the paddle.

15. The system as claimed in claim 11 further comprising:
bond wires that connect the integrated circuit to the first flat region.

16. The system as claimed in claim 11 further comprising:
a paddle formed by the first concave surfaces in a first surface of the conductive layer;
a die attach adhesive that attaches the integrated circuit to the paddle; and
wherein:
the second concave surfaces are smaller than the first concave surfaces.

17. The system as claimed in claim 16 wherein:
the second concave surfaces intersect the bottom region of the first concave surfaces.

18. The system as claimed in claim 16 wherein:
the conductive layer includes nickel, gold, palladium, copper, or a combination thereof.

19. The system as claimed in claim 16 further comprising:
wire bonding sections on the first flat region; and
wherein:
the integrated circuit is connected to the wire bonding sections with bond wires.

20. The system as claimed in claim 16 wherein:
the first concave surfaces creates a substantially larger area for bonding to the encapsulation than the second concave surfaces.
